(19) United States
(12) Patent Application Publication
(10) Pub. No.: US 2014/0319561 A1
(43) Pub. Date: Oct. 30, 2014

(54) SEMICONDUCTOR LIGHT EMITTING DEVICE WITH LIGHT TRANSMISSIVE ROUGHENED STRUCTURE AND METHOD OF MANUFACTURING THE SAME

(71) Applicant: ADVANCED OPTOELECTRONIC TECHNOLOGY, INC., Hsinchu Hsien (TW)

(72) Inventors: YA-CHI LIEN, Hukou (TW); TZU-CHIEN HUNG, Hukou (TW)

(73) Assignee: ADVANCED OPTOELECTRONIC TECHNOLOGY, INC., Hsinchu Hsien (TW)

(21) Appl. No.: 14/085,803

(22) Filed: Nov. 21, 2013

(30) Foreign Application Priority Data
Apr. 24, 2013 (CN) 2013101437088

(51) Int. Cl. H01L 33/38

(52) U.S. Cl. CPC H01L 33/38
USPC 257/98; 438/29

(57) ABSTRACT

A semiconductor light emitting device includes a semiconductor light emitting chip and a transparent conductive layer formed on the semiconductor light emitting chip. The semiconductor light emitting chip includes a substrate, and a first semiconductor layer, an active layer and a second semiconductor layer successively formed on the substrate. The transparent conductive layer is formed on the second semiconductor layer. A first electrode and a second electrode are respectively arranged on the transparent conductive layer and the first semiconductor layer. The transparent conductive layer has a roughened structure. A method of manufacturing a semiconductor light emitting device is also provided.

### BACKGROUND

1. Technical Field

The disclosure relates to semiconductor light emitting devices, and also relates to methods of manufacturing semiconductor light emitting devices.

2. Discussion of Related Art

Semiconductor light emitting devices are a new kind of popular light source, and are used in many fields. There are several factors affecting the light extraction efficiency of a semiconductor light emitting device, such as the material of the semiconductor layer, the construction of the light emitting structure, the transparency of the semiconductor light emitting device, total reflection of light that is radiated from the light emitting structure, etc.

A semiconductor light emitting chip is the most important component in a semiconductor light emitting device, and is a key factor affecting the light extraction efficiency of the semiconductor light emitting device. In a typical semiconductor light emitting device, the semiconductor light emitting chip has a transparent conductive layer, and a transparent protecting layer formed on the transparent conductive layer to protect the semiconductor light emitting chip. However, in practice, both the transparent conductive layer and the transparent protecting layer cause total reflection when light generated by the semiconductor light emitting chip exits therefrom, thereby decreasing the light extraction efficiency of the semiconductor light emitting device.

Therefore, it is desirable to provide a semiconductor light emitting device with high light extraction efficiency, and a method of manufacturing such a semiconductor light emitting device.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the present semiconductor light emitting device and method of manufacturing the semiconductor light emitting device. Moreover, in the drawings, like reference numerals designate corresponding parts throughout the several views.

FIG. 1 is a cross-sectional view of a semiconductor light emitting device in accordance with a first exemplary embodiment of the present disclosure.

FIG. 2 is a microscope view of a top of a transparent conductive layer of the semiconductor light emitting device of FIG. 1, prior to roughening treatment thereof.

FIG. 3 is similar to FIG. 2, but showing the top of the transparent conductive layer after the roughening treatment.

FIG. 4 is a cross-sectional view of a semiconductor light emitting device in accordance with a second exemplary embodiment of the present disclosure.

FIG. 5 is a cross-sectional view of a semiconductor light emitting device in accordance with a third exemplary embodiment of the present disclosure.

FIG. 6 is a cross-sectional view of a semiconductor light emitting device in accordance with a fourth exemplary embodiment of the present disclosure.

### DETAILED DESCRIPTION OF EMBODIMENTS

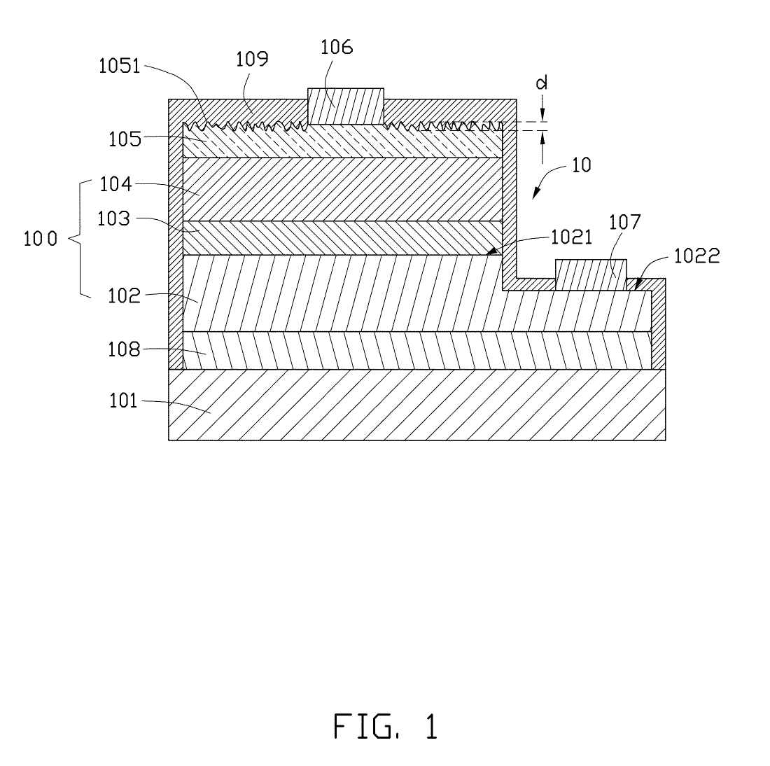

Referring to FIGS. 1 to 3, a semiconductor light emitting device in accordance with a first exemplary embodiment is shown. The semiconductor light emitting device includes a semiconductor light emitting chip 10, and a transparent conductive layer 105 formed on the semiconductor light emitting chip 10.

The semiconductor light emitting chip 10 includes a substrate 101, and a light emitting structure 100 formed on the substrate 101. The light emitting structure 100 includes a first semiconductor layer 102, an active layer 103 and a second semiconductor layer 104 successively formed over the substrate 101. The transparent conductive layer 105 is formed on the second semiconductor layer 104. Before forming the transparent conductive layer 105, a part of the area of the first semiconductor layer 102 is exposed via etching the second semiconductor layer 104 and the active layer 103. In the following description, a first area 1021 is defined as a portion of the first semiconductor layer 102 covered by the active layer 103, and a second area 1022 is defined as another portion of the first semiconductor layer 102 not covered by the active layer 103. A first electrode 106 is arranged on the transparent conductive layer 105. A second electrode 107 is arranged on the second area 1022 of the first semiconductor layer 102.

The substrate 101 is dielectric. The substrate 101 can be made of sapphire (Al₂O₃), silicon carbide (SiC), silicon (Si), gallium nitride (GaN), or zinc oxide (ZnO), etc.

Before forming the first semiconductor layer 102, a buffer layer 108 is formed on the substrate 101. The buffer layer 108 can lessen the degree of lattice mismatch between the first semiconductor layer 102 and the substrate 101. Accordingly, the first semiconductor layer 102 is formed on the buffer layer 108.

In this embodiment, the first semiconductor layer 102 is an N-type doped semiconductor layer, and the second semiconductor layer 104 is a P-type doped semiconductor layer. In an alternative embodiment, the first semiconductor layer 102 and the second semiconductor layer 104 can be a P-type doped semiconductor layer and an N-type doped semiconductor layer, respectively.

The transparent conductive layer 105 is formed on the second semiconductor layer 104, and the transparent conductive layer 105 can be made of indium tin oxide (ITO), indium oxide (In₂O₃), tin dioxide (SnO₂), ZnO, cadmium oxide (CdO), aluminum-doped zinc oxide (AZO), or indium-doped zinc oxide (IZO), etc.

In this embodiment, a roughened structure 1051 is formed in a portion of a surface of the transparent conductive layer 105 not occupied by the first electrode 106. The roughened structure 1051 is formed by roughening the surface of the transparent conductive layer 105. The roughening can be performed using a dry etching system or a wet etching system. Thus, the roughened structure 1051 is an integral part of a portion of the transparent conductive layer 105 not occupied by the first electrode 106. Put another way, the roughened structure 1051 is a topmost portion of the transparent conductive layer 105 not occupied by the first electrode 106. A depth of the roughened structure 1051 is shown as “d” in the FIG. 1. The depth of the roughened structure 1051 is typically in the range of about 30%-50% of the thickness of the transparent conductive layer 105. There are a plurality of micropores randomly distributed in a surface of the roughened structure 1051. A range of diameters of the micropores is from about 50 nm to about 200 nm. An example of a dry etching system is inductively-coupled plasma (ICP) etching. If a wet etching system is employed, an etching liquid can be hydrochloric acid (HCl), sulfuric acid (H₂SO₄), hydrofluoric acid (HF), buffer oxide etch (BOE), potassium hydroxide (KOH), phosphoric acid (H₃PO₄), or oxalic acid, etc.

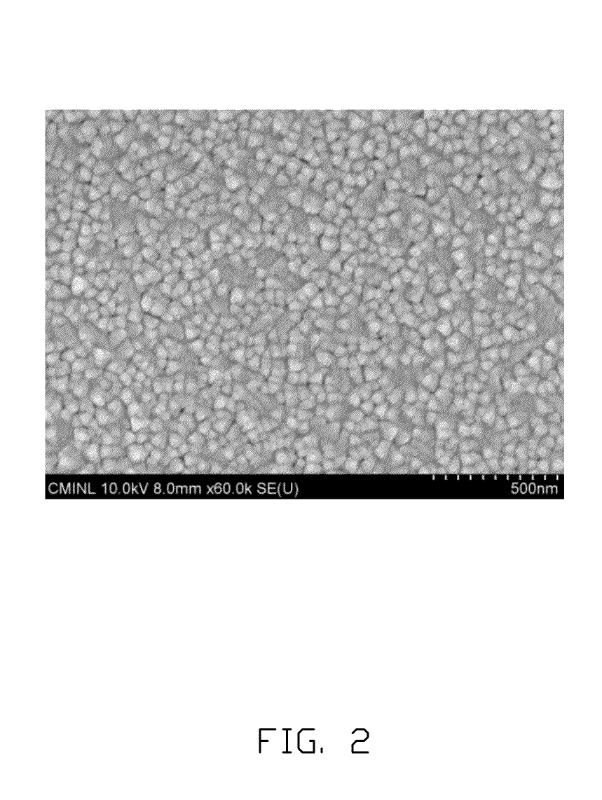

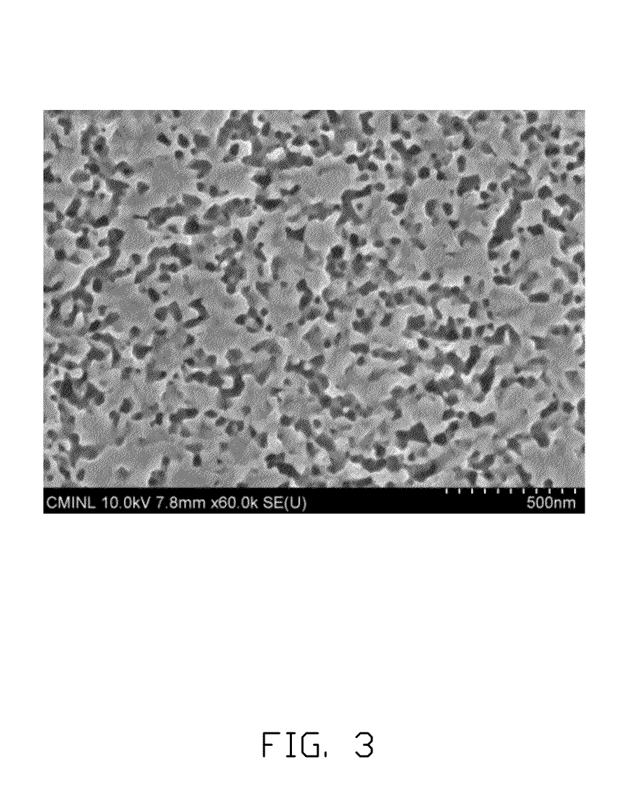

FIG. 2 and FIG. 3 show microscope views of a top of the transparent conductive layer 105 prior to roughening treatment thereof and after the roughening treatment, respectively.

Further, a transparent protecting layer 109 acting as a protector for the roughened structure 1051 is formed on the light emitting structure 100. The transparent protecting layer 109 is made of insulation material, such as silicon dioxide (SiO₂), or SiNₓ, etc. The transparent protecting layer 109 does not cover the first electrode 106, the second electrode 107, a peripheral surface of the substrate 101 nor a bottom surface of the semiconductor light emitting device.

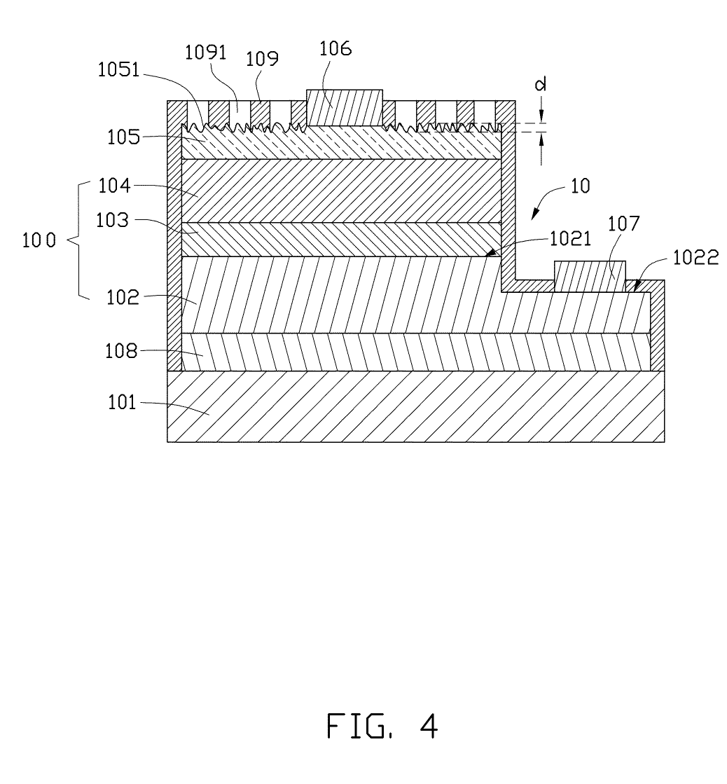

Referring to FIG. 4, a semiconductor light emitting device in accordance with a second exemplary embodiment is provided. The semiconductor light emitting device of the second embodiment is similar to that of the first embodiment. In order to further improve a light extraction efficiency of the semiconductor light emitting device, a plurality of holes 1091 are defined in the transparent protecting layer 109 by photolithography. The holes 1091 expose portions of the roughened structure 1051 of the transparent conductive layer 105 to an outside of the transparent protecting layer 109.

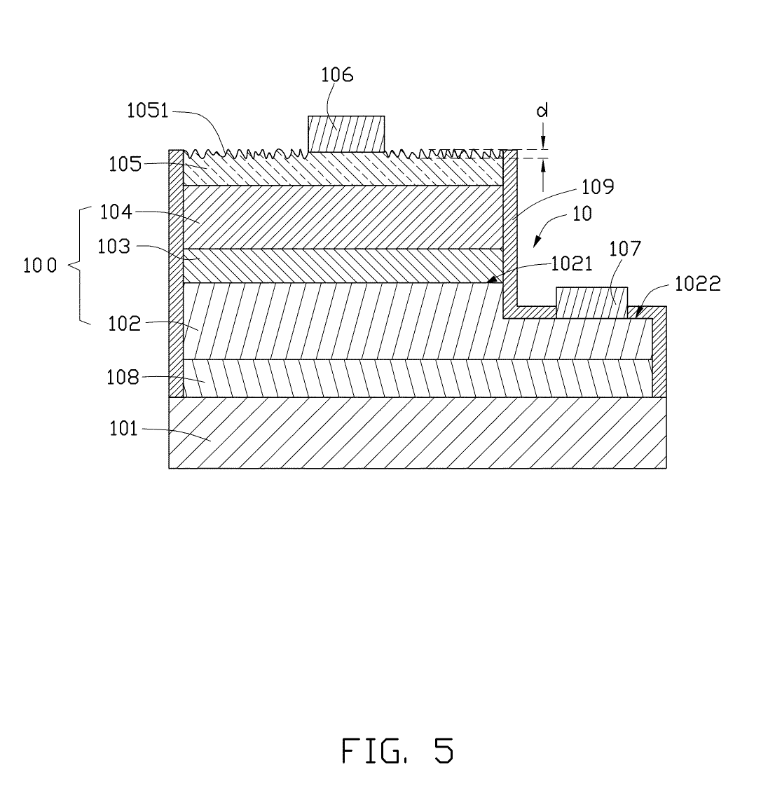

Referring to FIG. 5, a semiconductor light emitting device in accordance with a third exemplary embodiment is provided. Compared with the first embodiment, the transparent protecting layer 109 of the third embodiment further does not cover the top surface of the transparent conductive layer 105. Thus, all of the roughened structure 1051 is exposed, to achieve a higher light extraction efficiency.

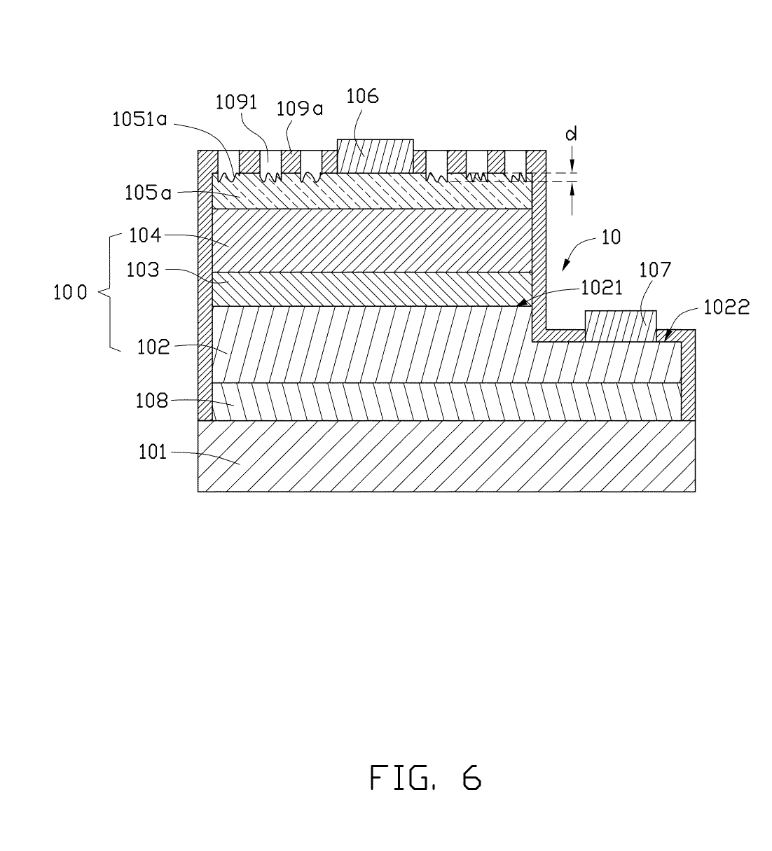

Referring to FIG. 6, a semiconductor light emitting device in accordance with a fourth exemplary embodiment is provided. Compared with the second embodiment, a transparent protection layer 109a of the fourth embodiment is formed on an unroughened top surface of a transparent conductive layer 105a. A roughened structure 1051a is provided at the bottoms of the holes 1091. That is, the roughened structure 1051a is discontinuous.

In the present disclosure, taking the first embodiment as an example, the roughened structure 1051 formed in the transparent conductive layer 105 can avoid total reflection and improve the light extraction efficiency. In addition, the roughened structure 1051 can increase a luminance and a range of angles of output light of the semiconductor light emitting device.

The present disclosure also provides an exemplary method of manufacturing a semiconductor light emitting device. When manufacturing the semiconductor light emitting device of the second embodiment, the method includes the following steps.

Step 1 is, providing a semiconductor light emitting chip 10 having a light emitting structure 100 and a transparent conductive layer 105 formed on the light emitting structure 100.

Step 2 is, arranging a first electrode 106 and a second electrode 107 on the transparent conductive layer 105 and the light emitting structure 100.

Step 3 is, roughening a surface of the transparent conductive layer 105 not occupied by the first electrode 106 to form a roughened structure 1051 of the transparent conductive layer 105.

Step 4 is, forming the transparent protecting layer 109 on a part of a surface of the semiconductor light emitting device. In this embodiment, the transparent protecting layer 109 is formed on, inter alia, substantially the entire roughened structure 1051 of the transparent conductive layer 105.

Step 5 is, etching the transparent protecting layer 109 to form a plurality of holes 1091, thereby exposing portions of the roughened structure 1051.

In step 1, the semiconductor light emitting chip 10 includes a substrate 101, and a buffer layer 108, a first semiconductor layer 102, an active layer 103 and a second semiconductor layer 104 successively formed on the substrate 101. The light emitting structure 100 includes the first semiconductor layer 102, the active layer 103 and the second semiconductor layer 104. The transparent conductive layer 105 is formed on part of the second semiconductor layer 104. The buffer layer 108 can lessen the degree of the lattice mismatch between the first semiconductor layer 102 and the substrate 101.

In step 3, a surface of the roughened structure 1051 of the transparent conductive layer 105 has a plurality of micropores, and a range of diameters of the micropores is from about 50 nm to about 200 nm.

It is understood that the exemplary method of manufacturing a semiconductor light emitting device is not limited to performing all of steps 1 through 5 in that sequence. For example, step 5 can be omitted. In such case, a semiconductor light emitting device in accordance with the first embodiment is formed, as shown in FIG. 1.

In another example, step 5 can be omitted, and step 4 can be modified such that the transparent protecting layer 109 is formed on a part of a surface of the semiconductor light emitting device not including the entire roughened structure 1051 of the transparent conductive layer 105. In such case, a semiconductor light emitting device in accordance with the third embodiment is formed, as shown in FIG. 5.

In another example, steps 1, 2, 4, 5 and 3 can be performed in that sequence. In such case, in step 3, the roughened structure 1051a is formed by roughening portions of the transparent conductive layer 105a at the bottoms of the holes 1091. Thus, a semiconductor light emitting device in accordance with the fourth embodiment is formed, as shown in FIG. 6.

It is to be further understood that even though numerous characteristics and advantages have been set forth in the foregoing description of embodiments, together with details of the structures and functions of the embodiments, the disclosure is illustrative only; and that changes may be made in detail, especially in matters of shape, size, and arrangement of parts within the principles of the disclosure to the full extent indicated by the broad general meaning of the terms in which the appended claims are expressed.

What is claimed is:

1. A semiconductor light emitting device, comprising:
a semiconductor light emitting chip comprising a substrate, and a first semiconductor layer, an active layer and a second semiconductor layer successively stacked on the substrate in that order;
a transparent conductive layer formed on the second semiconductor layer, the transparent conductive layer comprising a roughened structure, the roughened structure located at a surface of the transparent conductive layer;
a first electrode arranged on the transparent conductive layer; and
a second electrode arranged on the first semiconductor layer.

2. The semiconductor light emitting device of claim 1, wherein the roughened structure is located at a major area of the surface of the transparent conductive layer except an area where the first electrode is arranged on.

3. The semiconductor light emitting device of claim 1, wherein a depth of the roughened structure of the transparent conductive layer is a range of from about 30% to about 50% of a thickness of the transparent conductive layer.

4. The semiconductor light emitting device of claim 3, wherein the roughened structure comprises a plurality of micropores, and a range of diameters of the micropores is from about 50 nm to about 200 nm.

5. The semiconductor light emitting device of claim 1, further comprising a transparent protecting layer, the transparent protecting layer covering at least one part of the semiconductor light emitting device.

6. The semiconductor light emitting device of claim 5, wherein the transparent protecting layer is insulation material.

7. The semiconductor light emitting device of claim 5, wherein the transparent protecting layer covers the semiconductor light emitting device except the first electrode, the second electrode, a peripheral surface of the substrate and a bottom surface of the substrate.

8. The semiconductor light emitting device of claim 7, wherein a plurality of holes are defined in the transparent protecting layer to expose portions of the roughened structure of the transparent conductive layer.

9. The semiconductor light emitting device of claim 5, wherein the transparent protecting layer covers the semiconductor light emitting device except the first electrode, the transparent conductive layer, the second electrode, a peripheral surface of the substrate and a bottom surface of the substrate.

10. A method of manufacturing a semiconductor light emitting device, the method comprising:
providing a semiconductor light emitting chip having a light emitting structure and a transparent conductive layer formed on the light emitting structure;
arranging a first electrode on the transparent conductive layer and a second electrode on the light emitting structure;
roughening a surface of the transparent conductive layer not occupied by the first electrode to form a roughened structure of the transparent conductive layer; and
forming a transparent protecting layer that covers at least one part of the semiconductor light emitting device.

11. The method of claim 10, wherein the transparent protecting layer covers the semiconductor light emitting device except the first electrode, the second electrode, a peripheral surface of the substrate and a bottom surface of the substrate.

12. The method of claim 11, further comprising etching the transparent protecting layer to form a plurality of holes, wherein the holes expose portions of the roughened structure.

13. The method of claim 12, wherein the roughened structure is formed by roughening portions of the surface of the transparent conductive layer at the bottoms of the holes.

14. The method of claim 11, wherein the transparent protecting layer covers selected portions of the semiconductor light emitting device other than the transparent conductive layer.
